(19) United States
(12) Patent Application Publication
(10) Pub. No.: US 2026/0226220 A1
(43) Pub. Date: Aug. 6, 2026

(54) RESIN COMPOSITION FOR FORMING PHASE-SEPARATED STRUCTURE, METHOD FOR PRODUCING STRUCTURE HAVING PHASE-SEPARATED STRUCTURE, AND BLOCK COPOLYMER

(71) Applicants: TOKYO OHKA KOGYO CO., LTD., Kawasaki-shi (JP); Institute of Science Tokyo, Tokyo (JP)

(72) Inventors: Ryutaro SUGAWARA, Kawasaki-shi (JP); Takehiro SESHIMO, Kawasaki-shi (JP); Takahiro DAZAI, Kawasaki-shi (JP); Teruaki HAYAKAWA, Tokyo (JP); Ryota UEHARA, Tokyo (JP); Shinsuke MAEKAWA, Tokyo (JP)

(21) Appl. No.: 19/457,627

(22) Filed: Jan. 23, 2026

(30) Foreign Application Priority Data
Feb. 6, 2025 (JP) 2025-018235

(51) Int. Cl. C08F 299/00; G03F 7/00

(52) U.S. Cl. CPC C08F 299/00; G03F 7/0002

(57) ABSTRACT

A resin composition for forming a phase-separated structure having a period (L₀) of less than 24 nm and excellent vertical orientation. The resin composition contains a block copolymer (A) having a block (A1), a block (A2), and a block (A3) in this order, the block (A1) including a polymer having a repeating structure of a constituent unit represented by formula (a1), the block (A2) including a random copolymer having a structure in which a constituent unit represented by formula (a2-1) and a constituent unit represented by formula (a2-2) are randomly arranged, and the block (A3) including a polymer having a repeating structure of a constituent unit represented by formula (a3)

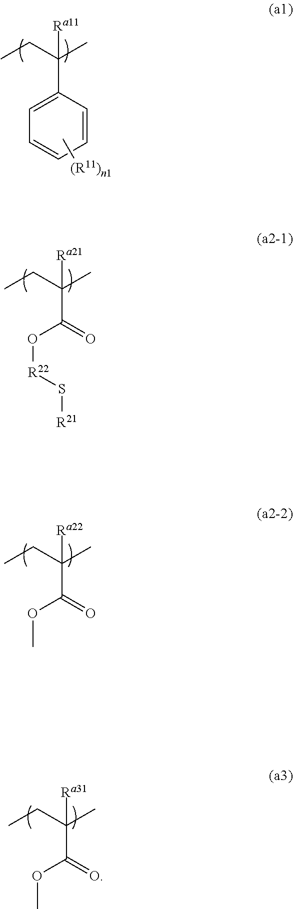

### RELATED APPLICATIONS

This application claims priority to Japanese Patent Application No. 2025-018235, filed Feb. 6, 2025, the entire content of which is incorporated herein by reference.

### BACKGROUND OF THE INVENTION

### Field of the Invention

The present invention relates to a resin composition for forming a phase-separated structure, a method for producing a structure having a phase-separated structure, and a block copolymer.

### Related Art

In recent years, following further miniaturization of a large-scale integrated circuit (LSI), a technique for processing a finer structure has been demanded. For such a demand, a technique has been developed for forming a finer pattern utilizing a phase-separated structure formed by self-organization of a block copolymer in which blocks incompatible with each other are bonded (see, for example, Patent Document 1).

The above-mentioned block copolymer undergoes separation (phase-separation) on a microscale due to repulsion between mutually incompatible blocks, and forms a structure with a regular periodic structure by heat treatment or the like. Specifically, the periodic structure may be cylindrical (columnar), lamellar (plate-like), or spheric (spherical).

In order to utilize the phase-separated structure of the block copolymer, it is essential for a self-organized nanostructure formed by microphase separation to be formed only in a specific region and oriented in a desired direction. In order to control a position and orientation of the nanostructure as described above, processes such as graphoepitaxy for controlling a phase separation pattern by a guide pattern and chemical epitaxy for controlling a phase separation pattern based on a difference in a chemical state of a substrate have been proposed.

The block copolymer forms a structure having a regular periodic structure by phase separation. The phrase “structural period” means a period of a phase structure observed when a structure having a phase-separated structure is formed and refers to a sum of lengths of phases incompatible with each other. In a case where a phase-separated structure forms a cylindrical structure perpendicular to a surface of a substrate, a structural period (L₀) is a distance between centers (pitch) of two adjacent cylindrical structures.

It has been known that a structural period (L₀) is determined by inherent polymerization properties such as a degree of polymerization N and the Flory-Huggins interaction parameter χ. That is, the larger the product “χ·N” of χ and N, the greater the mutual repulsion between different blocks in the block copolymer becomes. Therefore, in the case of χ·N>10.5 (hereinafter, referred to as “intensity separation limit”), repulsion between different blocks in the block copolymer is large, leading to a stronger tendency to cause phase separation. Accordingly, at the intensity separation limit, the structural period is approximately N^{2/3}·χ^{1/6} and a relationship of the following expression (1) is satisfied. That is, the structural period is proportional to the degree of polymerization N, which correlates with a molecular weight and a molecular weight ratio between different blocks.

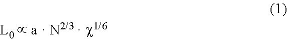

wherein L₀ denotes a structural period;
a is a parameter indicating a size of a monomer;
N denotes a degree of polymerization; and
× is an interaction parameter, and a higher value means higher phase separation performance.

Accordingly, the structural period (L₀) can be controlled by adjusting a composition and a total molecular weight of a block copolymer. Therefore, in order to form a structure having a smaller L₀ by utilizing a phase-separated structure formed by self-organization of a block copolymer, a method of decreasing a molecular weight of the block copolymer is considered. However, when the molecular weight of the block copolymer is simply reduced, the degree of polymerization (N) is lowered, which may cause a problem that phase separation does not occur. Thus, there is a demand for a material having a large interaction parameter (χ) (High χ material) so that phase separation occurs even when the molecular weight of the block copolymer is reduced.
Patent Document 1: Japanese Unexamined Patent Application, Publication No. 2008-36491

### SUMMARY OF THE INVENTION

In order to form a fine pattern by utilizing a phase-separated structure formed by self-organization of a block copolymer, it is preferable that the phase-separated structure formed by the block copolymer has a vertical orientation. However, generally known High χ materials hardly exhibit vertical orientation.

The present invention has been made in view of the above circumstances, and an object of the present invention is to provide a resin composition for forming a phase-separated structure capable of forming a phase-separated structure having a period (L₀) of less than 24 nm and excellent vertical orientation, a method for producing a structure having a phase-separated structure using the same, and a block copolymer for use in the resin composition for forming a phase-separated structure.

As a result of the inventors' extensive studies to solve the above problem, the present invention has been completed based on findings that the above object can be solved if a particular block copolymer (A) is used. Specifically, the present invention provides the following aspects.

A first aspect relates to a resin composition for forming a phase-separated structure, the resin composition containing a block copolymer (A),
the block copolymer (A) having a block (A1), a block (A2), and a block (A3) in this order,
the block (A1) being composed of a polymer having a repeating structure of a constituent unit represented by the following formula (a1),
the block (A2) being composed of a random copolymer having a structure in which a constituent unit represented by the following formula (a2-1) and a constituent unit represented by
the following formula (a2-2) are randomly arranged, the block (A3) being composed of a polymer having a repeating structure of a constituent unit represented by the following formula (a3),

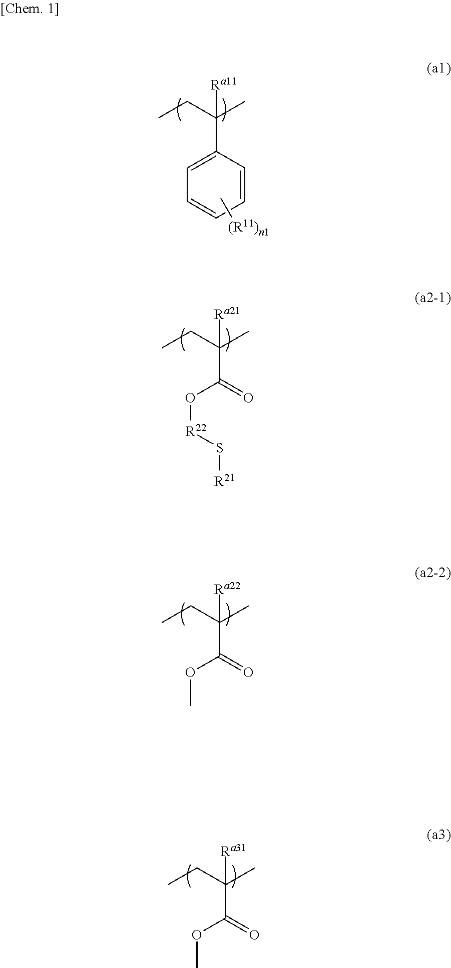

in which, in the formula (a1), R¹¹ is an alkyl group, and n1 is an integer of 0 or more and 5 or less,
in the formula (a2-1), R²¹ is an alkyl group which optionally has a silyl group, a fluorine atom, a carboxy group, an amino group, a hydroxy group, or a phosphoric acid group; and R²² is an alkylene group which optionally has a hydroxy group, and
in the formulas (a1), (a2-1), (a2-2), and (a3), R^{a11}, R^{a21}, R^{a22}, and R^{a31} are each independently a hydrogen atom, an alkyl group having 1 or more and 5 or less carbon atoms, or a halogenated alkyl group having 1 or more and 5 or less carbon atoms.

A second aspect relates to a method for producing a structure having a phase-separated structure, the method including: applying the resin composition for forming a phase-separated structure as described in the first aspect on a support to form a layer containing the block copolymer; and phase-separating the layer containing the block copolymer.

A third aspect relates to a block copolymer having a block (A1), a block (A2), and a block (A3) in this order,
the block (A1) being composed of a polymer having a repeating structure of a constituent unit represented by the following formula (a1),
the block (A2) being composed of a random copolymer having a structure in which a constituent unit represented by the following formula (a2-1) and a constituent unit represented by the following formula (a2-2) are randomly arranged,
the block (A3) being composed of a polymer having a repeating structure of a constituent unit represented by the following formula (a3),

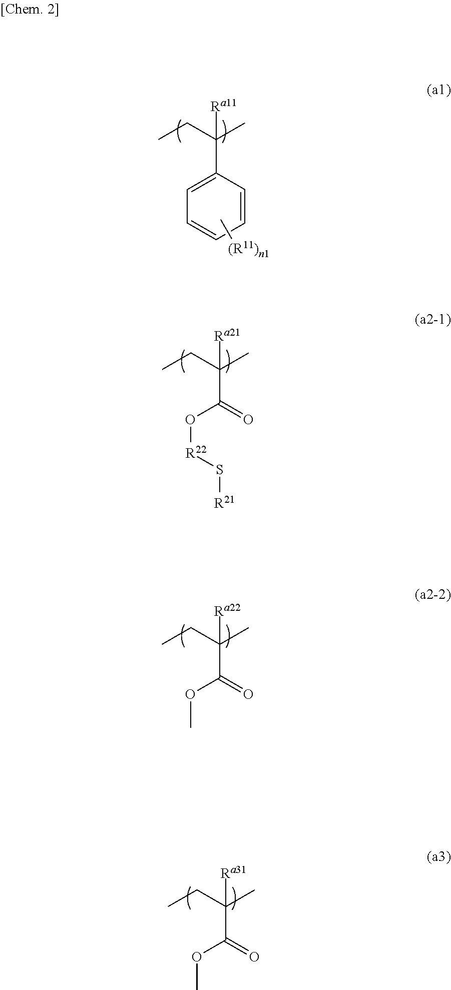

in which, in the formula (a1), R¹¹ is an alkyl group, and n1 is an integer of 0 or more and 5 or less,
in the formula (a2-1), R²¹ is an alkyl group which optionally has a silyl group, a fluorine atom, a carboxy group, an amino group, a hydroxy group, or a phosphoric acid group; and R²² is an alkylene group which optionally has a hydroxy group, and
in the formulas (a1), (a2-1), (a2-2), and (a3), R^{a11}, R^{a21}, R^{a22}, and R^{a31} are each independently a hydrogen atom, an alkyl group having 1 or more and 5 or less carbon atoms, or a halogenated alkyl group having 1 or more and 5 or less carbon atoms.

According to the present invention, it is possible to provide a resin composition for forming a phase-separated structure capable of forming a phase-separated structure having a period (L₀) of less than 24 nm and excellent vertical orientation, a method for producing a structure having a phase-separated structure using the same, and a block copolymer for use in the resin composition for forming a phase-separated structure.

### BRIEF DESCRIPTION OF THE DRAWINGS

FIG. 1 is a schematic process diagram illustrating an exemplary embodiment of a method for producing a structure having a phase-separated structure; and

FIG. 2 is a diagram illustrating an exemplary embodiment of an optional step.

### DETAILED DESCRIPTION OF THE INVENTION

Although embodiments of the present invention will be described below in detail, the present invention is not limited to the embodiments below in any way and can be implemented with modifications as appropriate within the scope of the object of the present invention.

### <<Resin Composition for Forming Phase-Separated Structure>>

A resin composition for forming a phase-separated structure according to a first aspect contains a block copolymer (A). The block copolymer (A) has a block (A1), block (A2), and a block (A3) in this order. The block (A1) is composed of a polymer having a repeating structure of a constituent unit represented by formula (a1). The block (A2) is composed of a random copolymer having a structure in which the constituent unit represented by the formula (a2-1) and a constituent unit represented by the formula (a2-2) are randomly arranged. The block (A3) is composed of a polymer having a repeating structure of a constituent unit represented by formula (a3).

### <Block Copolymer (A)>

The block copolymer (A) has a block (A1), block (A2), and a block (A3) in this order.

### [Block (A1)]

The block (A1) is composed of a polymer having a repeating structure of a constituent unit represented by the following formula (a1).

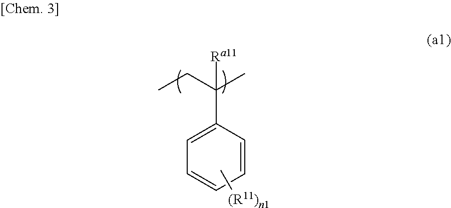

In the formula (a1), R¹¹ is an alkyl group; and n1 is an integer of 0 or more and 5 or less, and R^{a11} is a hydrogen atom, an alkyl group having 1 or more and 5 or less carbon atoms, or a halogenated alkyl group having 1 or more and 5 or less carbon atoms.

When n1 is an integer of 2 or more, a plurality of R¹¹s may be same as or different from each other.

The number of carbon atoms in the alkyl group as R¹¹ is preferably 1 or more and 5 or less. Examples of the alkyl group as R¹¹ include a methyl group, an ethyl group, an n-propyl group, an isopropyl group, an n-butyl group, a sec-butyl group, an isobutyl group, and a tert-butyl group.
n1 is preferably 0 or 1, and more preferably 0.

Examples of the alkyl group having 1 or more and 5 or less carbon atoms as R^{a11} include a methyl group, an ethyl group, a propyl group, an isopropyl group, an n-butyl group, a sec-butyl group, a tert-butyl group, an n-pentyl group, a neopentyl group, an isopentyl group, a sec-pentyl group, a 3-pentyl group, and a tert-pentyl group. The halogenated alkyl group having 1 or more and 5 or less carbon atoms as R^{a11} is a group in which a portion or all of hydrogen atoms in the alkyl group having 1 or more and 5 or less carbon atoms is substituted with a halogen atom. The halogen atom is particularly preferably a fluorine atom.

R^{a11} is preferably a hydrogen atom or an alkyl group having 1 or more and 5 or less carbon atoms, more preferably a hydrogen atom or a methyl group, and further preferably a hydrogen atom.

### [Block (A2)]

The block (A2) is composed of a random copolymer having a structure in which a constituent unit represented by the following formula (a2-1) and a constituent unit represented by the following formula (a2-2) are randomly arranged. Since the block (A2) has the constituent unit represented by the formula (a2-1) in addition to the constituent unit represented by the formula (a2-2), the interaction parameter of the block copolymer (A) can be increased, and a phase-separated structure having an excellent vertical orientation can be formed.

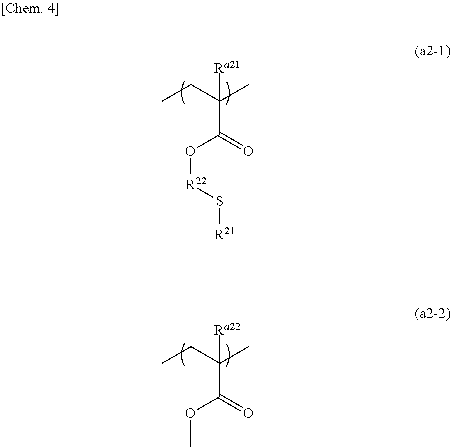

In the formula (a2-1), R²¹ is an alkyl group which optionally has a silyl group, a fluorine atom, a carboxy group, an amino group, a hydroxy group, or a phosphoric acid group; and R²² is an alkylene group which optionally has a hydroxy group, and
in the formulas (a2-1) and (a2-2), R^{a21} and R^{a22} are each independently a hydrogen atom, an alkyl group having 1 or more and 5 or less carbon atoms, or a halogenated alkyl group having 1 or more and 5 or less carbon atoms.
   (Constituent Unit Represented by Formula (a2-1))

The number of carbon atoms in the alkyl group as R²¹ is preferably 1 or more and 20 or less, more preferably 1 or more and 10 or less, and further preferably 1 or more and 5 or less. Note that when the alkyl group as R²¹ has a silyl group or a carboxy group, the number of carbon atoms in the silyl group and the carboxy group is not included in the number of carbon atoms in the alkyl group as R²¹. The alkyl group as R²¹ may be linear or branched, and is preferably linear. Examples of the alkyl group as R²¹ include a methyl group, an ethyl group, an n-propyl group, an isopropyl group, an n-butyl group, an isobutyl group, a sec-butyl group, a tert-butyl group, an n-pentyl group, an n-hexyl group, an n-heptyl group, an n-octyl group, an n-nonyl group, and an n-decyl group. Among them, a methyl group, an ethyl group, an n-propyl group, an n-butyl group, an n-pentyl group, an n-hexyl group, an n-heptyl group, or an n-octyl group is preferred, and a methyl group, an ethyl group, or an n-propyl group is more preferred.

When the alkyl group as R²¹ has a silyl group, a fluorine atom, a carboxy group, an amino group, a hydroxy group, or a phosphoric acid group, the silyl group and others are a substituent that substitutes a hydrogen atom of the alkyl group. Examples of the silyl group that may be included in the alkyl group as R²¹ include an alkylsilyl group such as a monoalkylsilyl group, a dialkylsilyl group, and a trialkylsilyl group. Among them, the trialkylsilyl group is preferred. The number of carbon atoms in the alkyl group of the alkylsilyl group is preferably 1 or more and 5 or less, and more preferably 1 or more and 3 or less. Examples of the alkyl group in the alkylsilyl group include a methyl group, an ethyl group, an n-propyl group, an isopropyl group, an n-butyl group, an isobutyl group, a sec-butyl group, a tert-butyl group, and an n-pentyl group. Among them, a methyl group or an ethyl group is preferred, and a methyl group is more preferred.

The number of carbon atoms in the alkylene group as R²² is preferably 2 or more, and more preferably 3 or more. In addition, the number of carbon atoms in the alkylene group is preferably 10 or less, and, from the viewpoint of the phase separation performance, more preferably 8 or less, further preferably 5 or less, and particularly preferably 4 or less. The number of carbon atoms in the alkylene group is most preferably 3. The alkylene group as R²² may be linear or branched, and is preferably linear.

When the alkylene group as R²² has a hydroxy group, the number of hydroxy groups is preferably 1 or more and 3 or less, more preferably 1 or 2, and further preferably 1.

Examples of the alkyl group having 1 or more and 5 or less carbon atoms and the halogenated alkyl group having 1 or more and 5 or less carbon atoms as R^{a21} may be the same as those listed for these groups as R^{a11}. R^{a21} is preferably a hydrogen atom or an alkyl group having 1 or more and 5 or less carbon atoms, more preferably a hydrogen atom or a methyl group, and further preferably a methyl group.

(Constituent Unit Represented by Formula (a2-2))

Examples of the alkyl group having 1 or more and 5 or less carbon atoms and the halogenated alkyl group having 1 or more and 5 or less carbon atoms as R^{a22} may be the same as those listed for these groups as R^{a11}. R^{a22} is preferably a hydrogen atom or an alkyl group having 1 or more and 5 or less carbon atoms, more preferably a hydrogen atom or a methyl group, and further preferably a methyl group.

### [Block (A3)]

The block (A3) is composed of a polymer having a repeating structure of a constituent unit represented by the following formula (a3).

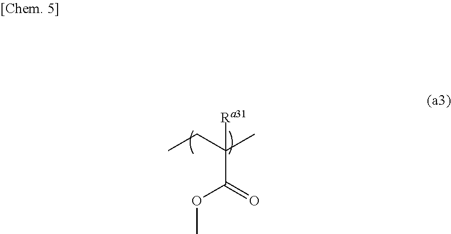

In the formula (a3), R^{a31} is a hydrogen atom, an alkyl group having 1 or more and 5 or less carbon atoms, or a halogenated alkyl group having 1 or more and 5 or less carbon atoms.

Examples of the alkyl group having 1 or more and 5 or less carbon atoms and the halogenated alkyl group having 1 or more and 5 or less carbon atoms as R^{a31} may be the same as those listed for these groups as R^{a11}. R^{a31} is preferably a hydrogen atom or an alkyl group having 1 or more and 5 or less carbon atoms, more preferably a hydrogen atom or a methyl group, and further preferably a methyl group.

In the block copolymer (A), the ratio of the number of moles of the constituent unit of the block (A1) to the total of the number of moles of the constituent unit of the block (A1), the number of moles of the constituent unit of the block (A2), and the number of moles of the constituent unit of the block (A3) is preferably 20 mol % or more and 80 mol % or less, more preferably 25 mol % or more and 75 mol % or less, and further preferably 30 mol % or more and 70 mol % or less.

In the block copolymer (A), the ratio of the number of moles of the constituent unit of the block (A2) to the total of the number of moles of the constituent unit of the block (A1), the number of moles of the constituent unit of the block (A2), and the number of moles of the constituent unit of the block (A3) is preferably 5 mol % or more and 60 mol % or less, more preferably 10 mol % or more and 50 mol % or less, and further preferably 15 mol % or more and 40 mol % or less.

In the block copolymer (A), the ratio of the number of moles of the constituent unit of the block (A3) to the total of the number of moles of the constituent unit of the block (A1), the number of moles of the constituent unit of the block (A2), and the number of moles of the constituent unit of the block (A3) is preferably 5 mol % or more and 65 mol % or less, more preferably 10 mol % or more and 60 mol % or less, and further preferably 15 mol % or more and 55 mol % or less.

In the block copolymer (A), the ratio of the total of the number of moles of the constituent unit of the block (A2) and the number of moles of the constituent unit of the block (A3) to the total of the number of moles of the constituent unit of the block (A1), the number of moles of the constituent unit of the block (A2), and the number of moles of the constituent unit of the block (A3) is preferably 20 mol % or more and 80 molo or less, more preferably 30 mol % or more and 70 mol % or less, and further preferably 40 mol % or more and 60 mol % or less.

In the block copolymer (A), the ratio of the number of moles of the constituent unit of the block (A2) to the total of the number of moles of the constituent unit of the block (A2) and the number of moles of the constituent unit of the block (A3) is preferably 20 mol % or more and 80 mol % or less, more preferably 25 mol % or more and 75 mol % or less, and further preferably 30 mol % or more and 70 mol % or less.

In the block (A2), the ratio of the number of moles of the constituent unit represented by the formula (a2-1) to the total of the number of moles of the constituent unit represented by the formula (a2-1) and the number of moles of the constituent unit represented by the formula (a2-2) is preferably 5 mol % or more and 80 mol % or less, more preferably 5 mol % or more and 70 mol % or less, and, from the viewpoint of vertical orientation, further preferably 5 mol % or more and 50 mol % or less, particularly preferably 5 mol % or more and 40 mol % or less, and most preferably 5 mol % or more and 30 mol % or less.

The block copolymer (A) may have another block in addition to the block (A1), the block (A2), and the block (A3). In a preferred embodiment, the block copolymer (A) is a triblock copolymer composed of the block (A1), the block (A2), and the block (A3).

A number average molecular weight (Mn) of the block copolymer (A) is not particularly limited, and is preferably 5,000 or more and 150,000 or less, more preferably 10,000 or more and 100, 000 or less, and further preferably 12, 000 or more and 50,000 or less. A polydispersity index (PDI) (Mw/Mn) of the block copolymer (A) is preferably 1.0 or more and 1.5 or less, more preferably 1.0 or more and 1.4 or less, and further preferably 1.0 or more and 1.3 or less. In this specification, the terms “number average molecular weight” (Mn) and “weight average molecular weight” (Mw) mean a number average molecular weight and a weight average molecular weight, respectively, in terms of standard polystyrene as measured by gel penetration chromatography (GPC), unless otherwise specified. When a value of Mn or Mw is described preceding a unit (g mol-1), the value represents a molar mass.

A method for producing the block copolymer (A) is not particularly limited, and the block copolymer can be produced by any known method. For example, the block copolymer can be produced by a production method utilizing the method described in Japanese Unexamined Patent Application, Publication No. 2022-20519.

### <Organic Solvent>

The resin composition for forming a phase-separated structure preferably contains an organic solvent. Any organic solvent may be used as the organic solvent as long as the organic solvent can dissolve each component to be used and form a homogeneous solution. In the related art, any organic solvent selected from known organic solvents as a solvent for a composition including a resin as a main component may be used.

Examples of the organic solvent include a lactone such as γ-butyrolactone; a ketone such as acetone, methyl ethyl ketone, cyclohexanone, methyl n-pentyl ketone, methyl isopentyl ketone, or 2-heptanone; a polyhydric alcohol such as ethylene glycol, diethylene glycol, propylene glycol, or dipropylene glycol; a polyhydric alcohol monoacetate such as ethylene glycol monoacetate, diethylene glycol monoacetate, propylene glycol monoacetate, or dipropylene glycol monoacetate; a derivative of the polyhydric alcohol or a derivative of a polyhydric alcohol having an ether bond, such as a monoalkyl ether of the polyhydric alcohol or the polyhydric alcohol monoacetate, such as a monomethyl ether, a monoethyl ether, a monopropyl ether, or a monobutyl ether of the polyhydric alcohol or the polyhydric alcohol monoacetate, or a monophenyl ether of the polyhydric alcohol or the polyhydric alcohol monoacetate [among them, propylene glycol monomethyl ether acetate (PGMEA) or propylene glycol monomethyl ether (PGME) is preferred]; a cyclic ether such as dioxane, or an ester other than a derivative of the polyhydric alcohols described above, such as methyl lactate, ethyl lactate (EL), methyl acetate, ethyl acetate, butyl acetate, methyl pyruvate, ethyl pyruvate, methyl methoxypropionate, or ethyl ethoxypropionate; and an aromatic organic solvent such as anisole, ethyl benzyl ether, cresyl methyl ether, diphenyl ether, dibenzyl ether, phenetole, butyl phenyl ether, ethylbenzene, diethylbenzene, pentylbenzene, isopropylbenzene, toluene, xylene, cymene, or mesitylene. The organic solvent may be used alone, or two or more thereof may be used as a mixed solvent. Among them, propylene glycol monomethyl ether acetate (PGMEA), propylene glycol monomethyl ether (PGME), cyclohexanone, or ethyl lactate (EL) is preferred.

The concentration of the organic solvent is determined appropriately according to a coating film thickness such that the resin composition for forming a phase-separated structure can be applied. The organic solvent is generally used such that a solid content concentration of the resin composition for forming a phase-separated structure is in a range of 0.2% by mass or more and 70% by mass or less, and preferably 0.2% by mass or more and 50% by mass or less.

### <Other Component>

The resin composition for forming a phase-separated structure may contain a component other than the block copolymer (A) and the organic solvent. Examples of other component include another resin such as a homopolymer, a surfactant, a dissolution inhibiting agent, a plasticizing agent, a stabilizing agent, a coloring agent, an anti-halation agent, a dye, a sensitizing agent, a base proliferating agent, and a basic compound.

### <<Method for Producing Structure Having Phase-Separated Structure>>

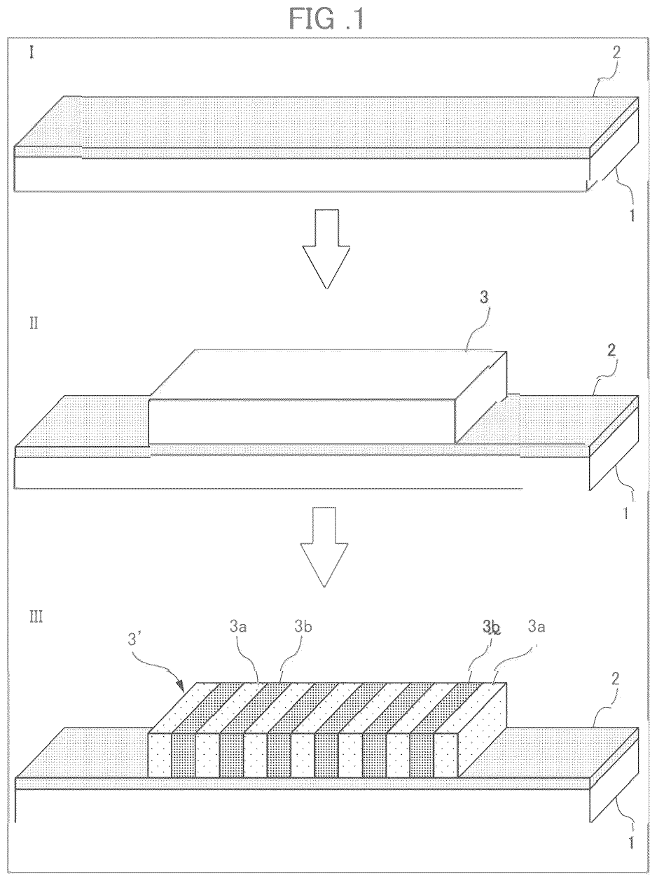

A method for producing a structure having a phase-separated structure according to a second aspect includes applying the resin composition for forming a phase-separated structure as described in the first aspect on a support to form a layer containing the block copolymer (hereinafter, referred to as “Step (i)”), and phase-separating the layer containing the block copolymer (hereinafter, referred to as “Step (ii)”). Hereinafter, such a method for producing a structure having a phase-separated structure will be described in detail with reference to FIG. 1. However, the method for producing a structure having a phase-separated structure is not limited to the specific aspect shown in FIG. 1.

FIG. 1 shows an exemplary embodiment of the method for producing a structure having a phase-separated structure. In the embodiment shown in FIG. 1, an undercoat agent is first applied on a support 1 to form an undercoat agent layer 2 (FIG. 1 (I)). Next, the resin composition for forming a phase-separated structure is applied on the undercoat agent layer 2 to form a layer (BCP layer) 3 containing a block copolymer (FIG. 1 (II), the above is Step (i)). Then, the resultant is annealed by heating to phase-separate the BCP layer 3 into phases 3a and phases 3b (FIG. 1 (III), Step (ii)). According to such a production method of the embodiment, that is, the production method including Step (i) and Step (ii), a structure 3′ having a phase-separated structure is produced on the support 1 on which the undercoat agent layer 2 is formed.

<Step (i)>

In Step (i), the resin composition for forming a phase-separated structure is applied on the support 1 to form the BCP layer 3. In the embodiment shown in FIG. 1, the undercoat agent is first applied on the support 1 to form the undercoat agent layer 2. By providing the undercoat agent layer 2 on the support 1, a hydrophilic-hydrophobic balance can be achieved between a surface of the support 1 and the layer (BCP layer) 3 containing the block copolymer. That is, when the undercoat agent layer 2 contains a resin component having a constituent unit constituting any block of the block copolymer, adhesion between a phase constituted by the block in the BCP layer 3 and the support 1 is improved. Accordingly, a phase-separated structure oriented in a direction perpendicular to the surface of the support 1 is easily formed by the phase separation of the BCP layer 3.

### Undercoat Agent:

A resin composition can be used as the undercoat agent. The resin composition for the undercoat agent can be appropriately selected from known resin compositions in the related art that is to be used for forming a thin film, depending on a type of a block constituting a block copolymer. The resin composition for the undercoat agent may be, for example, a thermopolymerizable resin composition or may be a photosensitive resin composition such as a positive-type resist composition or a negative-type resist composition. Furthermore, a non-polymerized film formed by applying a compound serving as a surface treating agent may be used as the undercoat agent layer. For example, a siloxane-based organic monolayer formed by applying phenethyltrichlorosilane, octadecyltrichlorosilane, hexamethyldisilazane, or the like as a surface treating agent can also be suitably used as the undercoat agent layer.

Examples of such a resin composition include a resin composition containing a resin having all constituent units constituting the respective blocks constituting the block polymer, and a resin composition containing a resin having all constituent units having high affinity for the respective blocks constituting the block copolymer. For example, a composition containing a resin having both styrene and methyl methacrylate as a constituent unit or a compound or a composition including both a moiety having a high affinity with styrene such as an aromatic ring and a moiety having a high affinity with methyl methacrylate (e.g., a highly polar functional group) is preferably used as the resin composition for the undercoat agent. Examples of the resin having both styrene and methyl methacrylate as a constituent unit include a random copolymer of styrene and methyl methacrylate, or an alternating polymer of styrene and methyl methacrylate (polymer in which each monomer is alternately copolymerized). Furthermore, examples of the composition including both a moiety having a high affinity with styrene and a moiety having a high affinity with methyl methacrylate include a composition containing a resin obtained by polymerizing at least a monomer having an aromatic ring and a monomer having a highly polar functional group as monomers. Examples of the monomer having an aromatic ring include a monomer having an aryl group in which one hydrogen atom is removed from an aromatic hydrocarbon ring such as a phenyl group, a biphenyl group, a fluorenyl group, a naphthyl group, an anthryl group, or a phenanthryl group; or a heteroaryl group in which a portion of carbon atoms constituting a ring on any of the above-mentioned groups is substituted with a heteroatom such as an oxygen atom, a sulfur atom, or a nitrogen atom. Furthermore, examples of the monomer having a highly polar functional group include a monomer having a trimethoxysilyl group, a trichlorosilyl group, an epoxy group, a glycidyl group, a carboxy group, a hydroxy group, a cyano group, or a hydroxyalkyl group in which a portion of hydrogen atoms in an alkyl group is substituted with a hydroxy group. Furthermore, examples of the compound including both a moiety having a high affinity with styrene and a moiety having a high affinity with methyl methacrylate include a compound including both an aryl group and a highly polar functional group such as phenethyltrichlorosilane; or a compound including both an alkyl group and a highly polar functional group such as an alkylsilane compound.

The resin composition for the undercoat agent can be produced by dissolving the above-mentioned resin in a solvent. Such a solvent may be any solvent as long as the solvent can dissolve a component to be used and form a homogeneous solution. For example, the same organic solvent component as one exemplified in the above-mentioned description for the resin composition for forming a phase-separated structure may be used.

A type of the support 1 is not particularly limited as long as the resin composition can be applied on the surface of the support 1. Examples thereof include a substrate made of an inorganic material such as a silicon, a metal (e.g., copper, chromium, iron, or aluminum), glass, titanium oxide, silica, or mica; a substrate made of an oxide such as SiO₂; a substrate made of a nitride such as SiN; a substrate made of an oxynitride such as SiON; or a substrate made of an organic material such as an acryl resin, polystyrene, cellulose, cellulose acetate, or a phenolic resin. Among them, a silicon substrate (Si substrate) or a metal substrate is suitable, a Si substrate or a copper substrate (Cu substrate) is more suitable, and a Si substrate is particularly suitable. A size or a shape of the support 1 is not particularly limited. The support 1 does not necessarily have a smooth surface, and substrates having various shapes can be appropriately selected. For example, a substrate having a curved surface, a flat plate having an uneven surface, or a flaky substrate may be used.

An inorganic and/or organic film may be provided on the surface of the support 1. Examples of the inorganic film include an inorganic antireflection film (inorganic BARC). Examples of the organic film include an organic antireflection film (organic BARC). The inorganic film can be formed, for example, by applying an inorganic antireflection film composition such as a silicon-based material on a support and baking the resultant. The organic film can be formed, for example, by applying a material for forming an organic film in which a resin component or the like constituting the organic film is dissolved in an organic solvent on a substrate using a spinner or the like, and baking the resultant under heating conditions of preferably 200° C. or higher and 300° C. or lower for preferably 30 seconds or more and 300 seconds or less and more preferably for 60 seconds or more and 180 seconds or less. This material for forming an organic film does not necessarily need sensitivity to light or electron beams unlike a resist film, and may or may not have the sensitivity. Specifically, a resist or a resin generally used for producing a semiconductor element or a liquid crystal display element may be used. Furthermore, the material for forming an organic film is preferably a material capable of forming an organic film that can be subjected to etching, particularly dry-etching so that an organic film pattern may be formed by etching the organic film using a pattern formed by processing the BCP layer 3 and made of the block copolymer and transferring the pattern to the organic film. Among them, a material capable of forming an organic film that can be subjected to etching such as oxygen plasma etching is preferably used. Such a material for forming an organic film may be a material used for forming an organic film such as organic BARC in the related art. Examples thereof include ARC series manufactured by Nissan Chemical Corporation, AR series manufactured by Rohm and Haas Japan Ltd., or SWK series manufactured by TOKYO OHKA KOGYO CO., LTD.

A method for forming the undercoat agent layer 2 by applying the undercoat agent on the support 1 is not particularly limited and may be any known method in the related art. For example, the undercoat agent layer 2 can be formed by applying the undercoat agent on the support 1 using a known method in the related art such as a spin coating or use of a spinner to form a coated film, and drying the coated film. A method for drying the coated film is not limited as long as a solvent contained in the undercoat agent can be volatilized, and, for example, baking may be used. In this case, a baking temperature is preferably 80° C. or higher and 300° C. or lower, more preferably 100° C. or higher and 270° C. or lower, and further preferably 120° C. or higher and 250° C. or lower. A baking time is preferably 30 seconds or more and 600 seconds or less and more preferably 60 seconds or more and 600 seconds or less. A thickness of the undercoat agent layer 2 after drying the coated film is preferably about 5 nm or more and 100 nm or less.

The surface of the support 1 may be previously cleaned before the undercoat agent layer 2 is formed on the support 1. Cleaning of the surface of the support 1 improves coatability of the undercoat agent. A known cleaning treatment method in the related art can be used, and examples thereof include an oxygen plasma treatment, an ozone oxidation treatment, an acid alkali treatment, or a chemical modification treatment.

After the undercoat agent layer 2 is formed, the undercoat agent layer 2 may be rinsed with a rinsing liquid such as a solvent, as necessary. Since an uncrosslinked portion or the like of the undercoat agent layer 2 is removed by rinsing, affinity with at least one block constituting a block copolymer is improved, and thus, a phase-separated structure having a cylindrical structure oriented in a direction perpendicular to the surface of the support 1 is likely to be formed. The rinsing liquid may be any liquid as long as the liquid can dissolve the uncrosslinked portion and, for example, a solvent such as propylene glycol monomethyl ether acetate (PGMEA), propylene glycol monomethyl ether (PGME), or ethyl lactate (EL), or a commercially available thinner liquid may be used. After the cleaning, post-baking may be performed in order to volatilize the rinsing liquid. A temperature condition during the post-baking is preferably 80° C. or higher and 300° C. or lower and more preferably 100° C. or higher and 270° C. or lower. A baking time is preferably 30 seconds or more and 500 seconds or less and more preferably 60 seconds or more and 240 seconds or less. A thickness of the undercoat agent layer 2 after such post-baking is preferably about 1 nm or more and 10 nm or less and more preferably about 2 nm or more and 7 nm or less.

Next, the layer (BCP layer) 3 containing the block copolymer is formed on the undercoat agent layer 2. A method of forming the BCP layer 3 on the undercoat agent layer 2 is not particularly limited, and, for example, may be a method including applying the resin composition for forming a phase-separated structure according to the above-mentioned embodiment on the undercoat agent layer 2 by a known method in the related art such as spin coating or use of a spinner to form a coated film and drying the coated film.

A thickness of the BCP layer 3 need only be sufficient for phase separation to occur. Considering a type of the support 1, or a size of a structural period or uniformity of a nanostructure of the phase-separated structure to be formed, or the like, the thickness is preferably 10 nm or more and 200 nm or less and more preferably 20 nm or more and 150 nm or less.

<Step (ii)>

In Step (ii), the BCP layer 3 formed on the support 1 is phase-separated. After Step (i), the support 1 is annealed by heating to form a phase-separated structure in which at least a part of the surface of the support 1 is exposed by selective removal of the block copolymer. That is, the structure 3′ having the phase-separated structure in which the phase 3a and the phase 3b are phase-separated is produced on the support 1. A temperature condition during the annealing treatment is preferably a glass transition temperature of a block copolymer used or higher and lower than its thermal decomposition temperature. For example, when the block copolymer is a polystyrene-polymethyl methacrylate (PS-PMMA) block copolymer (mass average molecular weight: 5000 or more and 150,000 or less), the temperature condition is preferably 180° C. or higher and 300° C. or lower. A heating time is preferably 30 seconds or more and 3600 seconds or less. The annealing treatment is preferably performed in a less reactive gas such as nitrogen.

### <Optional Step>

The method for producing a structure having a phase-separated structure is not limited to the above-mentioned embodiment and may include a step other than Step (i) and Step (ii) (optional step).

Such an optional step includes a step of selectively removing a phase constituted by at least one of the respective blocks constituting the block copolymer from the BCP layer 3 (hereinafter, referred to as “Step (iii)”), a guide pattern formation step, or the like.

Regarding Step (iii)

In Step (iii), a phase constituted by at least one of the respective blocks constituting the block copolymer is selectively removed from the BCP layer formed on the undercoat agent layer 2. This results in formation of a fine pattern (polymer nanostructure).

Examples of the method for selectively removing the phase constituted by the block include a method for subjecting the BCP layer to an oxygen plasma treatment or a method for subjecting the BCP layer to a hydrogen plasma treatment. For example, when the BCP layer containing the block copolymer (A) is phase-separated and then the BCP layer is subjected to an oxygen plasma treatment, a hydrogen plasma treatment, or the like, a phase constituted by the block (A1) is not selectively removed, but a phase constituted by the blocks (A2) and (A3) is selectively removed.

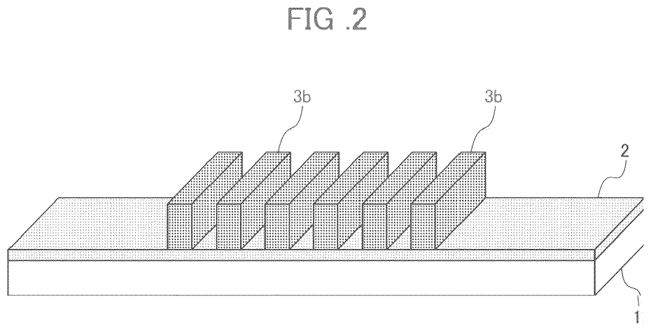

FIG. 2 shows an exemplary embodiment of Step (iii). In the embodiment shown in FIG. 2, the structure 3′ produced on the support 1 in Step (ii) is subjected to an oxygen plasma treatment to selectively remove the phases 3a, resulting in formation of a pattern (polymer nanostructure) constituted by the phases 3b apart from each other. In this case, the phase 3b is the phase constituted by the block (A1), and the phase 3a is the phase constituted by the blocks (A2) and (A3).

The support 1 with a pattern formed by phase separation of the BCP layer 3 made of the block copolymer as described above can be used as is, or a shape of the pattern (polymer nanostructure) on the support 1 can be changed by further heating. A temperature condition during the heating is preferably a glass transition temperature of the block copolymer used or higher and lower than its thermal decomposition temperature. The heating is preferably performed in a less reactive gas such as nitrogen.

### Regarding Guide Pattern Formation Step

The method for producing a structure having a phase-separated structure may include a step of providing a guide pattern on the undercoat agent layer (guide pattern formation step) between Step (i) and Step (ii) described above. This allows an array structure of the phase-separated structure to be controlled. For example, even for a block copolymer from which a fingerprint-shaped phase-separated structure is randomly formed when a guide pattern is not provided, a groove structure of a resist film can be provided on a surface of the undercoat agent layer to obtain a phase-separated structure oriented along the groove. According to this principle, a guide pattern may be provided on the undercoat agent layer 2. Further, in the case where a surface of the guide pattern has an affinity with any of blocks constituting the above-mentioned block copolymer, a phase-separated structure having a cylindrical structure oriented in a direction perpendicular to the surface of the support is likely to be formed.

The guide pattern can be formed using, for example, a resist composition. For the resist composition for forming the guide pattern, a resist composition having an affinity with any of blocks constituting the above block copolymer can be appropriately selected from resist compositions to be generally used for forming a resist pattern or a modified product thereof. The resist composition may be either a positive-type resist composition from which a positive-type pattern is formed, that is, an exposed area of a resist film is dissolved and removed or a negative-type resist composition from which a negative-type pattern is formed, that is, an unexposed area of a resist film is dissolved and removed, but a negative-type resist composition is preferred. The negative-type resist composition is preferably a resist composition that contains, for example, an acid generating agent and a base material component having a solubility in an organic solvent-containing developing solution that decreases under action of an acid, the base material component containing a resin component that has a constituent unit degraded under action of an acid to have an increased polarity. After a BCP composition is poured onto the undercoat agent layer on which the guide pattern is formed, an annealing treatment is performed to cause phase separation. Therefore, a composition capable of forming a resist film having excellent solvent resistance and heat resistance is preferably used as the resist composition for forming the guide pattern.

As described above, the present inventors provide the following aspects (1) to (5).
(1) A resin composition for forming a phase-separated structure, the resin composition containing a block copolymer (A),
the block copolymer (A) having a block (A1), a block (A2), and a block (A3) in this order,
the block (A1) being composed of a polymer having a repeating structure of a constituent unit represented by the following formula (a1),
the block (A2) being composed of a random copolymer having a structure in which a constituent unit represented by the following formula (a2-1) and a constituent unit represented by the following formula (a2-2) are randomly arranged,
the block (A3) being composed of a polymer having a repeating structure of a constituent unit represented by the following formula (a3),

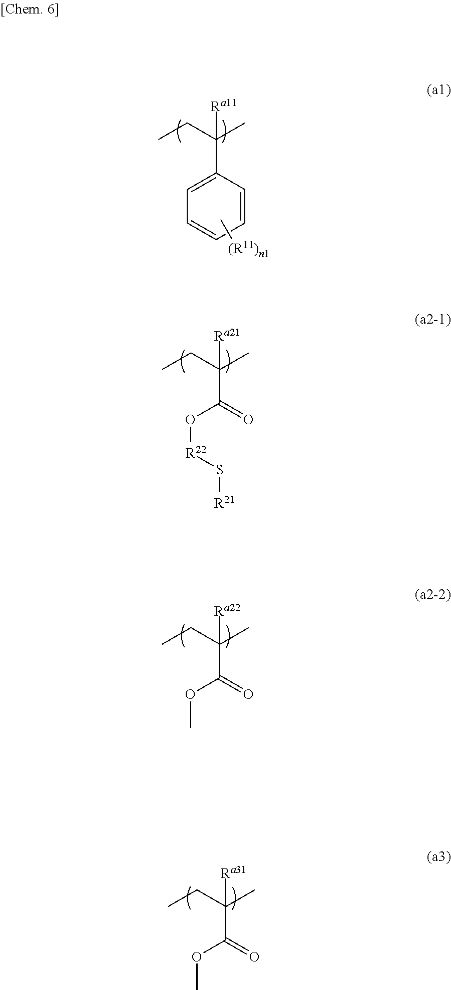

in which, in the formula (a1), R¹¹ is an alkyl group, and n1 is an integer of 0 or more and 5 or less,
in the formula (a2-1), R²¹ is an alkyl group which optionally has a silyl group, a fluorine atom, a carboxy group, an amino group, a hydroxy group, or a phosphoric acid group; and R²² is an alkylene group which optionally has a hydroxy group, and
in the formulas (a1), (a2-1), (a2-2), and (a3), R^{a11}, R^{a21}, R^{a22}, and R^{a31} are each independently a hydrogen atom, an alkyl group having 1 or more and 5 or less carbon atoms, or a halogenated alkyl group having 1 or more and 5 or less carbon atoms.
(2) The resin composition for forming a phase-separated structure according to aspect (1), in which the ratio of the number of moles of the constituent unit of the block (A2) is 20 mol or more and 80 mol % or less based on the total of the number of moles of the constituent unit of the block (A2) and the number of moles of the constituent unit of the block (A3).
(3) The resin composition for forming a phase-separated structure according to aspect (1) or (2), in which in the block (A2), the ratio of the number of moles of the constituent unit represented by the formula (a2-1) is 5 mol % or more and 80 mol % or less based on the total of the number of moles of the constituent unit represented by the formula (a2-1) and the number of moles of the constituent unit represented by the formula (a2-2).
(4) A method for producing a structure having a phase-separated structure, the method including:
applying the resin composition for forming a phase-separated structure according to any one of aspects (1) to (3) on a support to form a layer containing the block copolymer; and
phase-separating the layer containing the block copolymer.
(5) A block copolymer having a block (A1), a block (A2), and a block (A3) in this order,
the block (A1) being composed of a polymer having a repeating structure of a constituent unit represented by the following formula (a1),
the block (A2) being composed of a random copolymer having a structure in which a constituent unit represented by the following formula (a2-1) and a constituent unit represented by the following formula (a2-2) are randomly arranged,
the block (A3) being composed of a polymer having a repeating structure of a constituent unit represented by the following formula (a3),

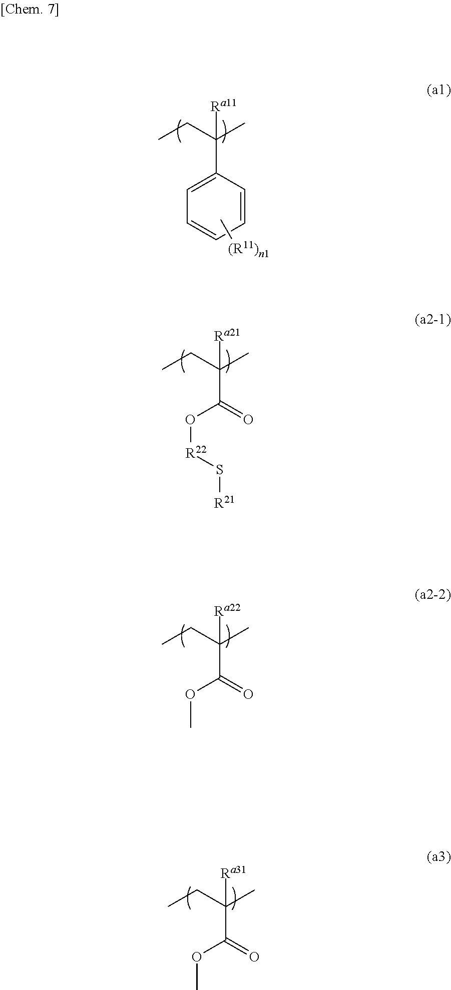

in which, in the formula (a1), R¹¹ is an alkyl group, and n1 is an integer of 0 or more and 5 or less,
in the formula (a2-1), R²¹ is an alkyl group which optionally has a silyl group, a fluorine atom, a carboxy group, an amino group, a hydroxy group, or a phosphoric acid group, and R²² is an alkylene group which optionally has a hydroxy group, and
in the formulas (a1), (a2-1), (a2-2), and (a3), R^{a11}, R^{a21}, R^{a22}, and R^{a31} are each independently a hydrogen atom, an alkyl group having 1 or more and 5 or less carbon atoms, or a halogenated alkyl group having 1 or more and 5 or less carbon atoms.

### Examples

Although the present invention will be described in more detail with reference to Examples, the present invention is not limited to Examples.

The following is an explanation of the block copolymers used in Examples and Comparative Example.

BCP-1 is a block copolymer represented by the following formula and having a block composed of polystyrene, and a block composed of a random copolymer of 2-hydroxy-3-(2, 2,2-trifluoroethylsulfanyl) propyl methacrylate and methyl methacrylate. The Mn of BCP-1 is 21, 000, and the ratio of the respective constituent units is 1:m:n=49:12: 39 (mol %).

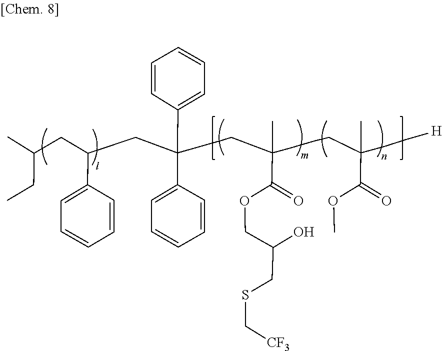

BCP-2 and -4: these are block copolymers represented by the following formula and having a block composed of polystyrene, a block composed of a random copolymer of 2-hydroxy-3-(2, 2,2-trifluoroethylsulfanyl) propyl methacrylate and methyl methacrylate, and a block composed of polymethyl methacrylate. The Mn of BCP-2 is 18, 700, and the ratio of the respective constituent units is 1:m:n: 0=53:14: 13:20 (mol %). The Mn of BCP-4 is 18,900, and the ratio of the respective constituent units is 1:m:n:o=51:5: 14:30 (mol %).

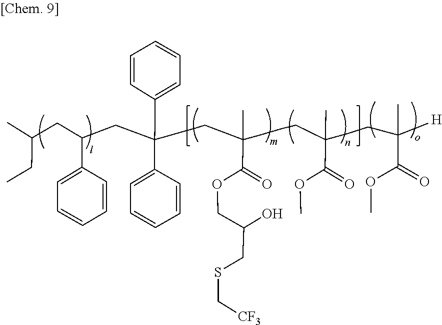

BCP-3 and -5: these are block copolymers represented by the following formula and having a block composed of polystyrene, a block composed of a random copolymer of 2-hydroxy-3-ethylsulfanylpropyl methacrylate and methyl methacrylate, and a block composed of polymethyl methacrylate. The Mn of BCP-3 is 21, 200, and the ratio of the respective constituent units is 1:m:n: 0=52:11: 10:27 (mol %).

The Mn of BCP-5 is 21, 400, and the ratio of the respective constituent units is 1:m:n: 0=53:5: 14:28 (mol %).

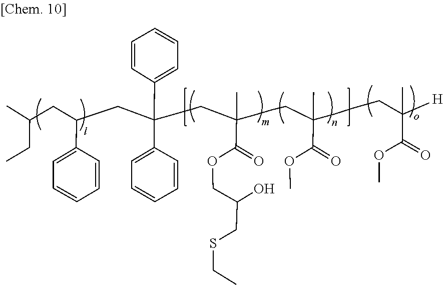

### <Production of Structure Having Phase-Separated Structure>

### (Preparation of Resin Composition for Forming Phase-Separated Structure)

The block copolymer (BCP) of the type shown in Table 1 and propylene glycol monomethyl ether acetate were mixed for dissolution to prepare a resin composition for forming a phase-separated structure (solid content concentration: 1.6% by mass) in each example.

### (Preparation of Undercoat Agent)

To prepare an undercoat agent, resins for undercoat agent NL-(1) to NL-(4) were provided. NL-(1) to NL-(4) are each a random copolymer composed of styrene (St), methyl methacrylate (MMA) and 2-hydroxyethyl methacrylate (HEMA). NL-(1) had a composition ratio (the ratio (mole ratio) of the respective constituent units in the structural formula) of St/MMA/HEMA=39/56/5, a number average molecular weight (Mn) of 24, 000, and a Water Contact Angle (W.C.A.) of 72°. NL-(2) had a composition ratio (the ratio (mole ratio) of the respective constituent units in the structural formula) of St/MMA/HEMA=49/46/5, a number average molecular weight (Mn) of 28,000, and Water Contact Angle (W.C.A.) of 75°. NL-(3) had a composition ratio (the ratio (mole ratio) of the respective constituent units in the structural formula) of St/MMA/HEMA=61/34/5, a number average molecular weight (Mn) of 30,000, and a Water Contact Angle (W.C.A.) of 77°. NL-(4) had a composition ratio (the ratio (mole ratio) of the respective constituent units in the structural formula) of St/MMA/HEMA=70/25/5, a number average molecular weight (Mn) of 29, 000, and a Water Contact Angle (W.C.A.) of 79°. One hundred parts by mass of each of the resins for undercoat agent NL-(1) to NL-(4) and 9900 parts by mass of propylene glycol monomethyl ether acetate were mixed for dissolution to prepare each of undercoat agents NL-1 to NL-4.

### (Step (i))

A 12-inch silicon wafer substrate was provided as a support. Any of the undercoat agents NL-1 to NL-4 was spin-coated on the silicon substrate, and then heated in an ambient atmosphere at 250° C. for 5 minutes. As a result, an undercoat agent layer composed of any of the resins for undercoat agent NL-(1) to NL-(4) and having a thickness of 30 nm was formed on the surface of the substrate. Next, a rinsing liquid composed of propylene glycol monomethyl ether (PGME) and propylene glycol monomethyl ether acetate (PGMEA) (PGME/PGMEA=7/3) was used to rinse the undercoat agent layer. Then, the undercoat agent layer was heated at 100° C. for 1 minute to volatilize the rinsing liquid. Next, the resin composition for forming a phase-separated structure according to each Example was spin-coated on the substrate, and then pre-baked at 90° C. for 60 seconds in a nitrogen atmosphere to form a layer containing the block copolymer (BCP layer) having a thickness of 36 nm.

(Step (ii))

The BCP layer formed on the substrate was annealed at 240° C. for 5 minutes in a nitrogen atmosphere to form a phase-separated structure.

(Step (iii))

The substrate on which the phase-separated structure was formed was subjected to an oxygen plasma treatment (200 mL/min, 40 Pa, 40° C., 200 W, 10 seconds) using TCA-3822 (manufactured by TOKYO OHKA KOGYO CO., LTD.) to selectively remove a polymethyl methacrylate-containing phase constituted by the block (A2) and the block (A3).

### [Evaluation of Resolution]

For the case where the undercoat agent NL-4 was used, an SEM image of a phase-separated structure on the surface of the obtained substrate was captured using “CG6300” manufactured by Hitachi High-Tech Corporation at a magnification of 100,000×. Next, analysis of a pattern period was carried out on the SEM image using “Terminal-PC software” manufactured by Hitachi High-Tech Corporation. The results of the analysis according to the following evaluation criteria are shown in Table 1 as “Resolution”.

### (Evaluation Criteria)

A: a period of less than 24 nm
B: a period of 24 nm or more

Note that in Comparative Example 1, any phase-separated structure was not formed, and the evaluation of the resolution was impossible.

### [Evaluation of Margin of Vertical Orientation]

For the case where each of the undercoat agents NL-1 to NL-4 was used, a phase-separated structure on the surface of the obtained substrate was observed using “CG6300” manufactured by Hitachi High-Tech Corporation at a magnification of 100,000×. As a result of the observation, a margin of vertical orientation was evaluated according to the following evaluation criteria. The results are shown in Table 1 as “Vertical orientation”.

### (Evaluation Criteria)

A: in all cases using NL-1 to NL-4, the phase-separated structure exhibited vertical orientation
B: in cases using any of NL-1 to NL-4, the phase-separated structure exhibited no vertical orientation
C: in all cases using NL-1 to NL-4, the phase-separated structure exhibited no vertical orientation

TABLE 1

| | BCP | Resolution | Vertical orientation |
|---|---|---|---|
| Comparative | BCP-1 | — | C |
| Example 1 | | | |
| Example 1 | BCP-2 | A | B |
| Example 2 | BCP-3 | A | B |
| Example 3 | BCP-4 | A | A |
| Example 4 | BCP-5 | A | A |

As shown in Table 1, when the compositions according to Examples, which contained the block copolymer (A), were used, a period (L₀) of less than 24 nm was achieved, and excellent vertical orientation was exhibited. On the other hand, when the composition according to Comparative Example, which contained a block copolymer other than the block polymer (A), was used, the vertical orientation was inferior.

What is claimed is:

1. A resin composition for forming a phase-separated structure, the resin composition comprising a block copolymer (A),
the block copolymer (A) having a block (A1), a block (A2), and a block (A3) in this order,
wherein the block (A1) comprises a polymer having a repeating structure of a constituent unit represented by formula (a1),
the block (A2) comprises a random copolymer having a structure in which a constituent unit represented by formula (a2-1) and a constituent unit represented by formula (a2-2) are randomly arranged, and
the block (A3) comprises a polymer having a repeating structure of a constituent unit represented by formula (a3), 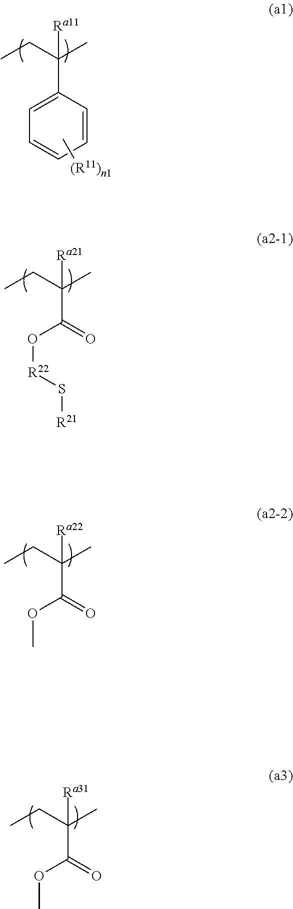
wherein, in the formula (a1), R¹¹ is an alkyl group, and n1 is an integer of 0 or more and 5 or less,
in the formula (a2-1), R²¹ is an alkyl group which optionally has a silyl group, a fluorine atom, a carboxy group, an amino group, a hydroxy group, or a phosphoric acid group; and R²² is an alkylene group which optionally has a hydroxy group, and
in the formulas (a1), (a2-1), (a2-2), and (a3), R^{a11}, R^{a21}, R^{a22}, and R^{a31} are each independently a hydrogen atom, an alkyl group having 1 or more and 5 or less carbon atoms, or a halogenated alkyl group having 1 or more and 5 or less carbon atoms.

2. The resin composition for forming a phase-separated structure according to claim 1, wherein a ratio of a number of moles of the constituent unit of the block (A2) is 20 mol % or more and 80 mol % or less based on a total of the number of moles of the constituent unit of the block (A2) and a number of moles of the constituent unit of the block (A3).

3. The resin composition for forming a phase-separated structure according to claim 1, wherein in the block (A2), a ratio of a number of moles of the constituent unit represented by the formula (a2-1) is 5 mol % or more and 80 mol % or less based on a total of the number of moles of the constituent unit represented by the formula (a2-1) and a number of moles of the constituent unit represented by the formula (a2-2).

4. A method for producing a structure having a phase-separated structure, the method comprising:
applying the resin composition for forming a phase-separated structure according to claim 1 on a support to form a layer comprising the block copolymer; and
phase-separating the layer comprising the block copolymer.

5. A block copolymer having a block (A1), a block (A2), and a block (A3) in this order,
wherein the block (A1) comprises a polymer having a repeating structure of a constituent unit represented by formula (a1),
the block (A2) comprises a random copolymer having a structure in which a constituent unit represented by formula (a2-1) and a constituent unit represented by formula (a2-2) are randomly arranged,
the block (A3) comprises a polymer having a repeating structure of a constituent unit represented by formula (a3), 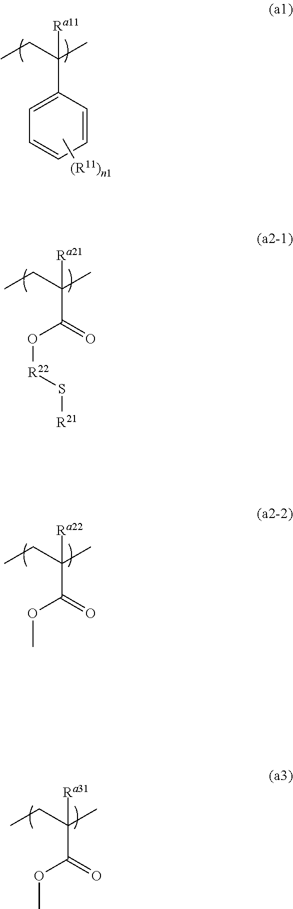
wherein, in the formula (a1), R¹¹ is an alkyl group, and n1 is an integer of 0 or more and 5 or less,
in the formula (a2-1), R²¹ is an alkyl group which optionally has a silyl group, a fluorine atom, a carboxy group, an amino group, a hydroxy group, or a phosphoric acid group, and R²² is an alkylene group which optionally has a hydroxy group, and
in the formulas (a1), (a2-1), (a2-2), and (a3), R^{a11}, R^{a21}, R^{a22}, and R^{a31} are each independently a hydrogen atom, an alkyl group having 1 or more and 5 or less carbon atoms, or a halogenated alkyl group having 1 or more and 5 or less carbon atoms.
